(19) United States
(12) Patent Application Publication
(10) Pub. No.: US 2015/0034155 A1
(43) Pub. Date: Feb. 5, 2015

(54) OPTOELECTRONIC DEVICE AND THE MANUFACTURING METHOD THEREOF

(71) Applicant: EPISTAR CORPORATION, Hsinchu (TW)

(72) Inventors: Yi-Hung LIN, Hsinchu (TW); Chien-Ming WU, Hsinchu (TW)

(73) Assignee: EPISTAR CORPORATION, Hsinchu (TW)

(21) Appl. No.: 13/957,958

(22) Filed: Aug. 2, 2013

(51) Int. Cl. H01L 31/0216

(52) U.S. Cl. CPC H01L 31/02168
USPC 136/256; 438/72

(57) ABSTRACT

An optoelectronic device includes: a semiconductor stack including an upper surface and a side surface; a first electrode formed on the upper surface of the semiconductor stack; a first anti-reflection structure formed on the first electrode and the upper surface; and a second anti-reflection structure different from the first anti-reflection structure formed on the side surface.

### TECHNICAL FIELD

The application relates to an optoelectronic device and the manufacturing method thereof, in particular, the optoelectronic device is a solar cell device.

### DESCRIPTION OF BACKGROUND ART

Because of the shortage of the petroleum energy resource and the promotion of the environment protection, people continuously and actively study the art related to the replaceable energy and the regenerative energy resources in order to reduce the dependence of petroleum energy resource and the influence on the environment. The solar cell is an attractive candidate among those replaceable energy and the regenerative energy resources because the solar cell can directly convert solar energy into electricity. In addition, there are no harmful substances like carbon oxide or nitride generated during the process of generating electricity so there is no pollution to the environment.

The basic structure of a solar-cell element includes an optoelectronic stack, a front electrode formed on the upper surface of the optoelectronic stack, and a back electrode formed on the bottom surface of the optoelectronic stack. Furthermore, for receiving most solar light, the upper surface of the optoelectronic stack may be covered by an anti-reflecting layer.

The solar-cell element can further connect to a base via a bonding layer or adhesion to form a light-absorbing device. In additional, the base can further include a circuit to electrically connect to the electrode of the solar cell element via a conductive structure such as metal wire.

### SUMMARY OF THE DISCLOSURE

An optoelectronic device includes: a semiconductor stack including an upper surface and a side surface; a first electrode formed on the upper surface of the semiconductor stack; a first anti-reflection structure formed on the first electrode and the upper surface; and a second anti-reflection structure different from the first anti-reflection structure formed on the side surface.

An optoelectronic device includes: a semiconductor stack including an upper surface and a side surface; a first electrode including Ag or Ag alloy formed on the upper surface of the semiconductor stack; a first anti-reflection structure including a barrier layer directly formed on the first electrode and an anti-reflection stack comprising oxide formed on the barrier layer, wherein the barrier layer is configured to insulate Ag of the first electrode from oxide of the anti-reflection stack; and a second anti-reflection structure including the anti-reflection stack formed on the side surface.

A manufacturing method of an optoelectronic device includes steps of: providing a wafer structure including a substrate and a semiconductor stack formed on the substrate and having an upper surface; forming a first electrode on the upper surface of the semiconductor stack; forming a barrier layer on the first electrode and the upper surface of the semiconductor stack; forming a trench through the semiconductor stack and penetrating the substrate with a depth; forming an anti-reflection stack on the barrier layer and in the trench; and forming a plurality of optoelectronic units by dicing the wafer structure in accordance with the trench.

### BRIEF DESCRIPTION OF THE DRAWINGS

FIGS. 1A to 1G show a manufacturing method of an optoelectronic device in accordance with an embodiment of the present application.

### DETAILED DESCRIPTION OF PREFERRED EMBODIMENTS

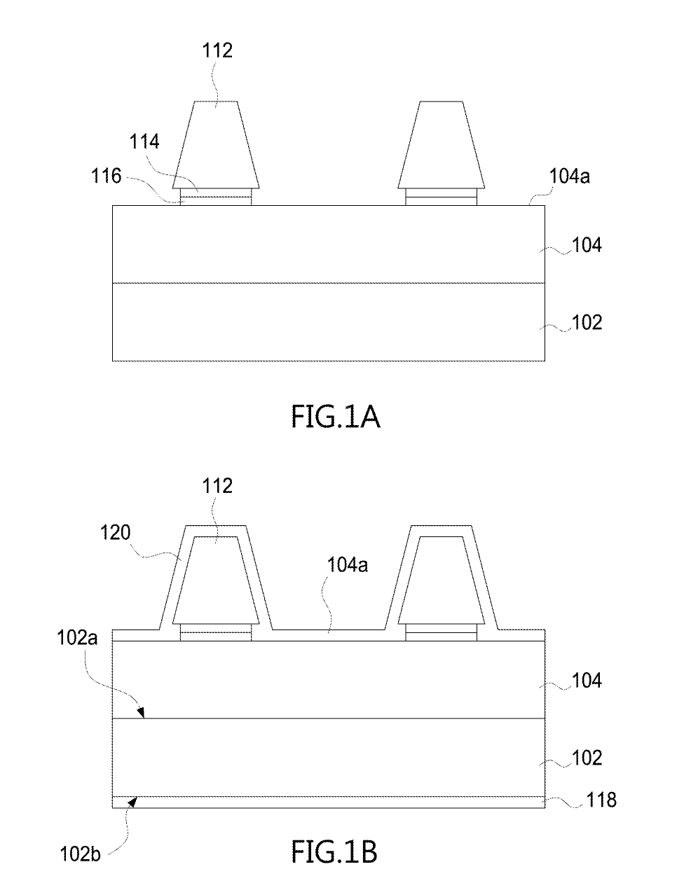

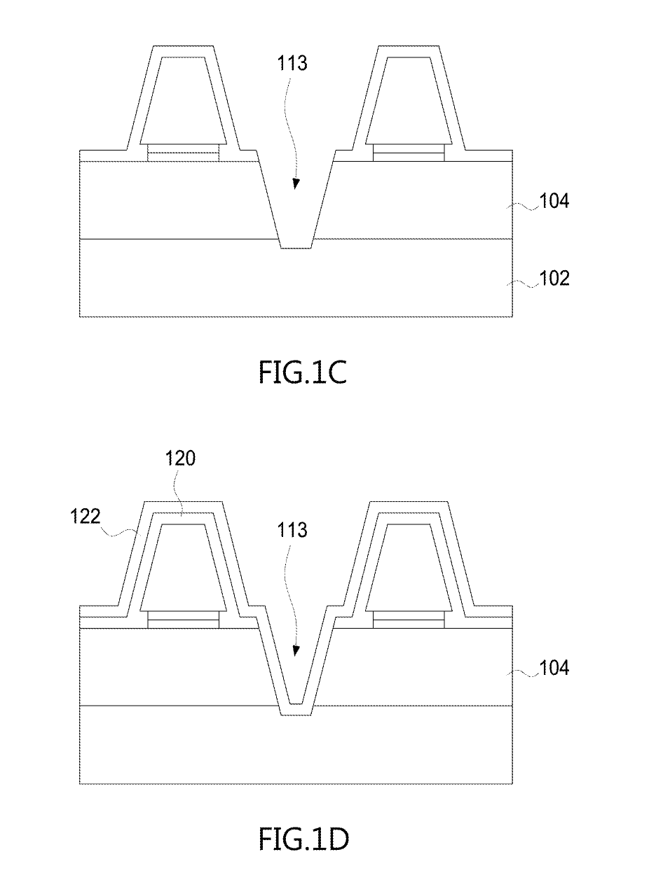

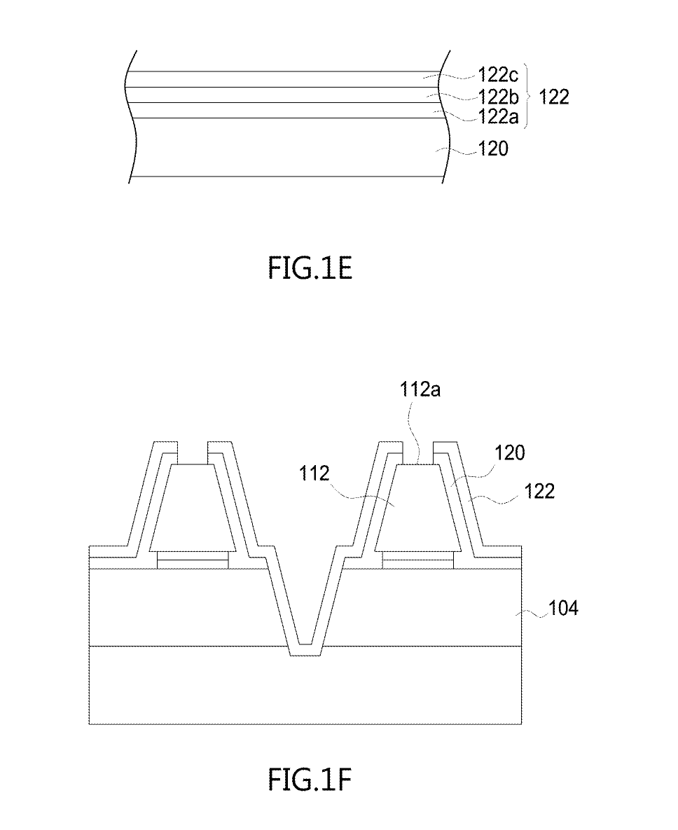

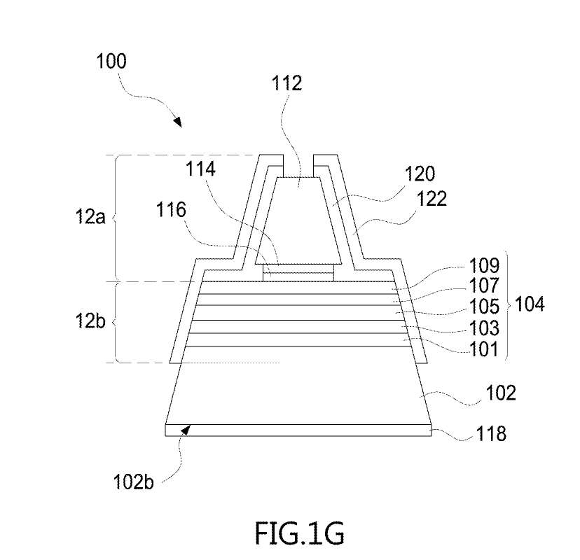

Referring to FIGS. 1A to 1F, a manufacturing method of an optoelectronic device in accordance with an embodiment of the present application is disclosed.

As shown in FIG. 1A, a wafer structure is provided and includes a substrate 102, a semiconductor stack 104 including an upper surface 104a formed on the substrate 102, and a first electrode 112 formed on the semiconductor stack 104. A first contact layer 114 including metal can be formed between the first electrode 112 and the semiconductor stack 104. A second contact layer 116 including semiconductor can be formed between the semiconductor stack 104 and the first contact layer 114. The substrate 102 can be a conductive substrate, and the semiconductor stack 104 can be a III-V group solar-cell stack formed on an upper surface 102a of the substrate 102, and the first electrode 112 can include Ag or Ag alloy.

As shown in FIG. 1B, a barrier layer 120 is formed on the first electrode 112 and the upper surface 104a of the semiconductor stack 104 conformably, and the substrate 102 is thinned by grinding or polishing for removing the undesired epitaxial layer grown on the bottom surface of the substrate 102, and a second electrode 118 can be formed on a bottom surface of the substrate 102 and is opposite to the first electrode 112. The barrier layer 120 can include a material inactive with Ag, and to be specific, the barrier layer 120 can include Si₃N₄, and the thickness of the barrier layer 120 is less than 150 Å.

As shown in FIG. 1C, a trench 113 can be formed to define a plurality of optoelectronic units, and the trench 113 is through the semiconductor stack 104 and penetrates the substrate 102 with a depth. As shown in FIG. ID, an anti-reflection stack 122 is formed on the barrier layer 120 and in the trench 113 conformably. The trench 113 is for dicing the wafer structure and can be formed by photolithography, and a photoresist (not shown) of the photolithography is removed by a solution after forming the trench 113. The solution for removing the photoresist can include alkaline solution such as AZ300T, and the photoresist can be entirely removed by AZ300T, and the first electrode 112 including Ag can be protected by the barrier layer 120 from the solution. Conventionally, when forming Ag electrode in a solar cell, ACE(Acetone) solution is used for removing the photoresist of photolithography instead of strong acid or base solution which damages Ag electrode. However, ACE has difficulty to remove the photoresist completely and the remained photoresist is adverse to Ag electrode, and the electrical feature of the Ag electrode may be influenced.

As shown in FIG. 1E, the anti-reflection stack 122 can have a first layer 122a including TiO₂ on the barrier layer 120, a second layer including Al₂O₃ on the first layer 122a, and a third layer 122c including SiO₂ on the second layer 122b. The barrier layer 120 formed between the first electrode 112 including Ag and the anti-reflection stack 122 including oxide, in particular, TiO₂. A conventional solar cell with an Au front electrode has TiO₂ as the anti-reflection layer. Because of the high stability of Au, TiO₂ can be directly formed on the Au front electrode, however the cost of Au has been largely raised year by year, and some solar-cell vendor turned to Ag for replacing Au for the material of front electrode of solar-cell. Ag front electrode can lower the cost of fabricating a solar-cell, but Ag is a relatively unstable material in comparison with Au and is easily to react with the anti-reflection layer including TiO₂.

As shown in FIG. 1F, the first electrode 112 includes a top surface 112a, and the barrier layer 120 and the anti-reflection stack 122 directly above the top surface 112a are removed, therefore the top surface 112a can he exposed.

As shown in FIG. 1G, after a dicing process, an optoelectronic device 100 can be formed. The optoelectronic device 100 includes: a substrate 102; a semiconductor stack 104 formed on the substrate 102 and including an upper surface 104a and a side surface 104b; a first electrode 112 formed on the semiconductor stack 104; a first anti-reflection structure 12a including the barrier layer 120 and the anti-reflection stack 122 on the first electrode 112 and the upper surface 104a; a second anti-reflection structure 12b including the anti-reflection stack 122 formed on the side surface 104b, wherein the anti-reflection stack 122 can be formed on the barrier layer 120 and the side surface 104b, preferably, the anti-reflection stack 122 can be conformably on the barrier layer 120 and the side surface 104b; and a second electrode 118 formed on a bottom surface 102b of the substrate 102. The first electrode 112 includes Ag or Ag alloy, and the anti-reflection stack 122 includes oxide, and the barrier layer 120 including Si₃N₄ is configured to separate the anti-reflection stack 122 from the first electrode 112. Accordingly, the anti-reflection stack 122 including oxide is for anti-reflection function, and the barrier layer 120 is for preventing anti-reflection stack 122 reacting with the first electrode 112. Further referring to FIG. 1E, the anti-reflection stack 122 includes a first layer 122a, a second layer 122b, and the first anti-reflection structure 12a and the second anti-reflection structure 12b include common first layer 122a, second layer 122b and third layer 122c. The first anti-reflection structure 12a can have more stacked layers than the second anti-reflection structure 12b.

The substrate 102 can be a conductive substrate having a first junction formed by doping a material, for example, the substrate can include Ge. The semiconductor stack 104 includes: a first tunnel junction 101 formed on the substrate 102; a first semiconductor layer 103 formed on the first tunnel junction 101, wherein the first semiconductor layer 103 has a second junction formed by sequentially doping two different materials therein during epitaxial growth process; a second tunnel junction 105 formed on the first semiconductor layer 103; and a second semiconductor layer 107 formed on the second tunnel junction 105, wherein the second semiconductor layer 107 has a third junction formed by sequentially doping two different materials therein during epitaxial growth process. The first junction, second junction and third junction include p-n junction or p-i-n junction respectively. The material of the first semiconductor layer 103 can be GaAs, and the material of the second semiconductor layer 107 can be InGaP. The first tunnel junction 101 and the second tunnel junction 105 can include InGaAs/AlGaInAs junction and InGaP/AlGaInAs junction, respectively. The optoelectronic device 100 further includes a light-absorbing layer 109 on the second semiconductor layer 107 for receiving more light from outside, and the material of the light-absorbing layer 109 can include AlInP.

Although the present application has been explained above, it is not the limitation of the range, the sequence in practice, the material in practice, or the method in practice. Any modification or decoration for present application is not detached from the spirit and the range of such.

What is claimed is:

1. An optoelectronic device, comprising:
a semiconductor stack comprising an upper surface and a side surface;
a first electrode formed on the upper surface of the semiconductor stack;
a first anti-reflection structure formed on the first electrode and the upper surface; and
a second anti-reflection structure different from the first anti-reflection structure formed on the side surface.

2. The optoelectronic device according to claim 1, wherein the first anti-reflection structure and the second anti-reflection layer comprise multiple stacked layers respectively, and the first anti-reflection structure comprises more stacked layers than that of the second anti-reflection structure.

3. The optoelectronic device according to claim 2, wherein the first anti-reflection structure comprises four stacked layers and the second anti-reflection structure comprises three stacked layers.

4. The optoelectronic device according to claim 2, wherein the first anti-reflection structure comprises a barrier layer comprising SiNₓ directly formed on the first electrode and the upper surface.

5. The optoelectronic device according to claim 4, wherein the barrier layer has a thickness not exceeding 150 Å.

6. The optoelectronic device according to claim 4, wherein the first anti-reflection structure comprises a first layer comprising TiO₂ covering the barrier layer, a second layer comprising Al₂O₃ covering the first layer, and a third layer comprising SiO₂ covering the second layer.

7. The optoelectronic device according to claim 2, wherein the second anti-reflection structure comprises a first layer comprising TiO₂ covering the side surface, a second layer comprising Al₂O₃ covering the first layer, and a third layer comprising SiO₂ covering the second layer.

8. The optoelectronic device according to claim 7, wherein the first anti-reflection structure and the second anti-reflection structure comprise common first layer, second layer and third layer.

9. The optoelectronic device according to claim l , wherein the first electrode comprises Ag or Ag Alloy.

10. The optoelectronic device according to claim 1, further comprising a conductive substrate under the semiconductor stack, and a second electrode under the conductive substrate.

11. An optoelectronic device, comprising:
a semiconductor stack comprising an upper surface and a side surface;
a first electrode comprising Ag or Ag alloy formed on the upper surface of the semiconductor stack;
a first anti-reflection structure comprising a barrier layer directly formed on the first electrode and an anti-reflection stack comprising oxide formed on the barrier layer, wherein the barrier layer is configured to insulate Ag of the first electrode from oxide of the anti-reflection stack; and
a second anti-reflection structure comprising the anti-reflection stack formed on the side surface.

12. The optoelectronic device according to claim 11, wherein the barrier layer comprises SiNₓ.

13. The optoelectronic device according to claim 11, wherein the stacked layers comprise a first layer comprising TiO₂ covering the barrier layer, a second layer comprising Al₂O₃ covering the first layer, and a third layer comprising SiO₂ covering the second layer.

14. The optoelectronic device according to claim 11, further comprising a conductive substrate under the semiconductor stack, and a second electrode under the conductive substrate.

15. The optoelectronic device according to claim 11, wherein the barrier layer has a thickness not exceeding 150 Å.

16. A manufacturing method of an optoelectronic device, comprising steps of:
providing a wafer structure comprising a substrate and a semiconductor stack formed on the substrate and having an upper surface;
forming a first electrode on the upper surface of the semiconductor stack;
forming a barrier layer on the first electrode and the upper surface of the semiconductor stack;
forming a trench through the semiconductor stack and penetrating the substrate with a depth;
forming an anti-reflection stack on the barrier layer and in the trench; and
forming a plurality of optoelectronic units by dicing the wafer structure along the trench.

17. The manufacturing method of an optoelectronic according to claim 16, wherein the first electrode comprises Ag or Ag alloy, and the barrier layer is inactive with Ag.

18. The manufacturing method of an optoelectronic device according to claim 16, further comprising removing the barrier layer and the anti-reflection stack directly above a top surface of the first electrode before forming the plurality of optoelectronic units.

19. The manufacturing method of an optoelectronic device according to claim 16, further comprising forming a second electrode on a bottom surface of the substrate before forming the trench, wherein the substrate is a conductive substrate.

20. The manufacturing method of an optoelectronic device according to claim 16, wherein the barrier layer is conformably formed on the first electrode and the upper surface, and the anti-reflection stack is conformably formed on the barrier layer and in the trench.
